(19) United States
(12) Patent Application Publication
(10) Pub. No.: US 2023/0290813 A1
(43) Pub. Date: Sep. 14, 2023

(54) CAPACITOR INCLUDING LATERAL PLATES AND METHOD FOR FORMING A CAPACITOR

(71) Applicant: STMicroelectronics (Crolles 2) SAS, Crolles (FR)

(72) Inventor: Marios BARLAS, Grenoble (FR)

(73) Assignee: STMicroelectronics (Crolles 2) SAS, Crolles (FR)

(21) Appl. No.: 18/178,333

(22) Filed: Mar. 3, 2023

(30) Foreign Application Priority Data
Mar. 11, 2022 (GR) 20220100227
Apr. 21, 2022 (FR) 2203677

(51) Int. Cl. H01L 27/08

(52) U.S. Cl. CPC H01L 28/60; H01L 27/0805

(57) ABSTRACT

A device includes at least one capacitor. The capacitor includes an assembly of two metal pads and at least two metal plates, each plate extending at least from one pad to the other, a first insulating layer conformally covering said assembly, a second conductive layer conformally covering the first layer.

### BACKGROUND

### Technical Field

The present disclosure generally concerns electronic components, and more particularly capacitors, and their manufacturing methods.

### Description of the Related Art

The miniaturization of electronic devices is a major issue in the development of new technologies. This results in a need to miniaturize the different components of electronic devices, that is, resistors, capacitors, transistors, etc.

In particular, there is a need to form capacitors having a significant capacitance for small dimensions.

### BRIEF SUMMARY

An embodiment overcomes all or part of the disadvantages of known devices including a capacitor.

An embodiment provides a device including at least one capacitor, the capacitor including an assembly of two metal pads and at least two metal plates, each plate extending at least from one pad to the other, a first insulating layer conformally covering said assembly, a second conductive layer conformally covering the first layer.

Another embodiment provides a method of manufacturing a device including at least one capacitor, the method including: forming an assembly of two metal pads and at least two metal plates, each plate extending at least from one pad to the other. The method includes forming a first insulating layer conformally covering said assembly. The method includes forming a second conductive layer conformally covering the first layer.

According to an embodiment, two neighboring plates of a same capacitor are separated by two portions of the first insulating layer and a portion of the second conductive layer located between the two portions of the first insulating layer.

According to an embodiment, the pads include a metal core and a sheath made of the same material as the plates.

According to an embodiment, the device includes a plurality of capacitors, the second layers of the capacitors being coupled by portions of the second layer.

According to an embodiment, the capacitor includes a conductive track in a third insulating layer of the device, the pads resting on the track.

According to an embodiment, the capacitor includes a fourth insulating layer covering the conductive track, the pads crossing the third insulating layer, the fourth layer being located between the plates and the track.

According to an embodiment, the portions of the assembly located above the fourth layer are entirely covered with the first insulating layer, the first insulating layer being entirely covered with the second layer.

According to an embodiment, the method includes, prior to forming the assembly, forming the conductive track in the third insulating layer, and forming the fourth layer on the track and on the third layer.

According to an embodiment, wherein forming the assembly incudes forming of a stack of layers including an alternation of fifth layers made of the material of the plates and of sixth sacrificial layers.

According to an embodiment, the sixth layers are made of a material selectively etchable over the material of the fifth layers.

According to an embodiment, wherein forming the assembly includes, after forming the stack of layers, etching the stack to form the plates from the fifth layers.

According to an embodiment, wherein forming the assembly includes the etching of the sixth layers after etching the stack.

According to an embodiment, forming the first insulating layer and the second conductive layer by an atomic layer deposition method.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 shows a cross-section view of an embodiment of a capacitor, according to an embodiment;

FIG. 2 shows a cross-section view and a perspective view of a step of a method of manufacturing the embodiment of FIG. 1, according to an embodiment;

FIG. 3 shows a cross-section view and a perspective view of another step of the method of manufacturing the embodiment of FIG. 1, according to an embodiment;

FIG. 4 shows a cross-section view and a perspective view of another step of the method of manufacturing the embodiment of FIG. 1, according to an embodiment;

FIG. 5 shows a cross-section view and a perspective view of another step of the method of manufacturing the embodiment of FIG. 1, according to an embodiment;

FIG. 6 shows a cross-section view and a perspective view of another step of the method of manufacturing the embodiment of FIG. 1, according to an embodiment;

FIG. 7 shows a cross-section view and a perspective view of another step of the method of manufacturing the embodiment of FIG. 1, according to an embodiment;

FIG. 8 shows a cross-section view and a perspective view of another step of the method of manufacturing the embodiment of FIG. 1, according to an embodiment;

FIG. 9 shows a top view of another step of the method of manufacturing the embodiment of FIG. 1, according to an embodiment; and

FIG. 10 shows a perspective view of another step of the method of manufacturing the embodiment of FIG. 1, according to an embodiment.

### DETAILED DESCRIPTION

In the following description, certain details are set forth in order to provide a thorough understanding of various embodiments of devices, methods and articles. However, one of skill in the art will understand that other embodiments may be practiced without these details. In other instances, well-known structures and methods associated with, for example, image sensors, semiconductor fabrication processes, etc., have not been shown or described in detail in some figures to avoid unnecessarily obscuring descriptions of the embodiments.

Unless the context requires otherwise, throughout the specification and claims which follow, the word “comprise” and variations thereof, such as “comprising,” and “comprises,” are to be construed in an open, inclusive sense, that is, as “including, but not limited to.”

Reference throughout this specification to “one embodiment,” or “an embodiment” means that a particular feature, structure or characteristic described in connection with the embodiment is included in at least one embodiment. Thus, the appearances of the phrases “in one embodiment,” or “in an embodiment” in various places throughout this specification are not necessarily referring to the same embodiment, or to all embodiments. Furthermore, the particular features, structures, or characteristics may be combined in any suitable manner in one or more embodiments to obtain further embodiments.

The headings are provided for convenience only, and do not interpret the scope or meaning of this disclosure or the claims.

The sizes and relative positions of elements in the drawings are not necessarily drawn to scale. For example, the shapes of various elements and angles may not be drawn to scale, and some of these elements may be enlarged and positioned to improve drawing legibility. Further, the particular shapes of the elements as drawn are not necessarily intended to convey any information regarding the actual shape of particular elements, and have been selected solely for ease of recognition in the drawings. Geometric references are not intended to refer to ideal embodiments. For example, a reference to square-shaped does not mean that an element has a geometrically perfect square shape.

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front,” “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

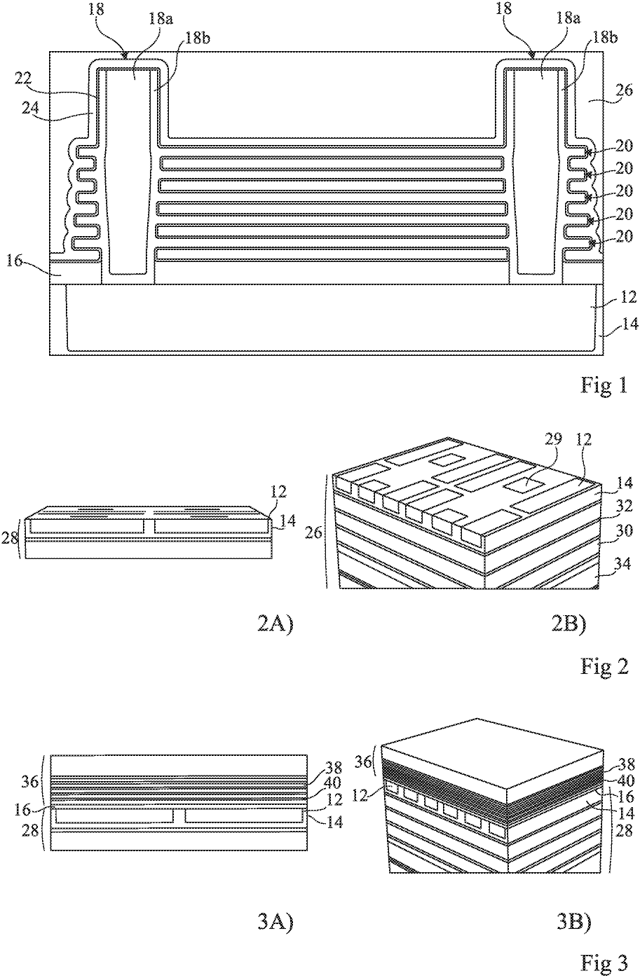

FIG. 1 shows a cross-section view of an embodiment of a capacitor 10. FIG. 1 shows a single capacitor 10. However, a capacitor of higher capacitance may be formed by coupling in parallel a plurality of capacitors 10.

Capacitor 10 includes a conductive track 12, preferably made of metal. Conductive track 12 is for example located in an insulating layer 14. Layer 14 and conductive track 12 for example correspond to a metallization level of an interconnection level formed during the steps called “Back End Of Line,” for example, a level called “M5.” Track 12 is flush with the upper surface of layer 14. Track 12 is for example made of copper. Layer 14 is for example made of silicon oxide.

A layer 16 covers layer 14 and tracks 12. Layer 16 is preferably in contact with track 12. Layer 16 is made of a material capable of being selectively etched over the material of conductive track 14. By a first material capable of being selectively etched over a second material, there is meant that there exists at least one etching method enabling to etch the first material at least twice faster, preferably at least ten times faster, than the second material. Layer 16 is for example made of SiCN.

As a variant, layer 16 may be replaced with a stack, not shown, of a SiCN layer and an Al2O3 layer. The Al2O3 layer for example has a thickness in the range from 5 nm to 20 nm, preferably a thickness substantially equal to 10 nm.

Capacitor 10 includes pads 18. The capacitor includes at least two pads 18. Pads 18 rest on track 12. Pads 18 thus cross layer 16. The pads extend vertically, that is, in a direction orthogonal to the plane of the upper surface of track 12. Pads 18 preferably have identical dimensions. In particular, pads 18 have the same height, that is, a same distance between the lower surface, that is, the surface closest to track 12, and the upper surface, that is, the surface most distant from track 12.

Pads 18 include a conductive core 18a and a conductive sheath 18b. Sheath 18b is made of metal, for example, of titanium nitride. Core 18a is for example made of metal, for example, of tungsten or of titanium. Sheath 18b covers and is in contact with the lower surface of core 18a. Sheath 18b covers, and is in contact with, the lateral walls of core 18a. For example, the sheath does not cover the upper surface of core 18a. The upper surface of core 18a is thus exposed. Sheath 18b covers, and is in contact with, track 12. Sheath 18b thus separates core 18a from track 12.

Capacitor 10 further includes plates 20. Capacitor 10 includes at least two plates 20. In the example of FIG. 1, capacitor 10 includes five plates. Plates 20 extend in plane parallel to one another. Plates 20 for example extend in planes parallel to the plane of the upper surface of track 12. The planes where plates 20 are located are located between the upper surface of pads 18 and the upper surface of layer 16. Plates 20 are thus not in contact with layer 16. Preferably, plates 20 extend in planes located under the upper surface of pads 18.

Plates 20 extend at least between the two pads 18. Plates 20 for example extend around pads 20. Thus, each plate 20 for example extends over the entire contour of each pad 18, in the plane of said plate 20.

Each plate 20 is in contact with the conductive sheath 18b of each of pads 18. Preferably, each plate 20 is in contact with the conductive sheath 18b of each of pads 18 over the entire contour of each pad 18, in the plane of said plate 20. All the plates are thus electrically coupled to pads 18, and to one another by pads 18. Pads 18 and plates 20 form a first electrode of capacitor 10.

Plates 20 are for example made of the same material as sheath 18b. The plates are for example made of titanium nitride. Plates 20 for example have substantially parallelepipedal shapes. Plates 20 preferably have identical dimensions.

The structure formed of pads 18 and of plates 20 is entirely covered with an insulating layer 22. By entirely covered, there is meant that the entire surface of each pad 18 which is not in contact with plates 20, layer 16, and track 12 is covered with, and in contact with, layer 22, and that the entire surface of each plate 20 which is not in contact with pads 18 is covered with, and in contact with, layer 22. Layer 22 particularly covers the upper and lower surfaces of each plate 20. Layer 22 is for example made of HfO2, of Al2O3, of La2O3, of ZrO2, of TiO2, or of Barium Strontium Titanate (BST, Ba_x Sr_(1-x) TiO_3). In other words, all the portions of the assembly including pads 18 and plates 20 located above layer 16, that is, located on the side of layer 16 opposite to the side in contact with track 12 are covered by the layer 22.

Layer 22 further at least partially covers layer 16. Layer 22 covers the portions of layer 16 located under plates 20, in particular between pads 18.

Capacitor 10 further includes a conductive layer 24. Layer 24 is preferably made of metal, for example of titanium nitride or of tungsten. Layer 24 covers layer 22, preferably the entire layer 22. In particular, the portions of layer 22 covering the lower and upper surfaces of plates 20 are covered with layer 24.

Layer 24 is a continuous layer. In other words, all the portions of layer 24 are connected. Layer 24 forms a second electrode of capacitor 10.

Each surface of each plate 20 is covered, preferably entirely, with layer 22 and layer 24, layer 24 and plate 20 being separated by layer 22. Layer 22 is in contact with the plate 20 on which it rests and layer 22 is in contact with layer 24. Each plate 20 is separated from the portion of layer 24 resting on said plate 20 by a portion of layer 22. Preferably, each plate 20 is only separated from the portion of layer 24 resting on said plate 20 by a portion of layer 22. Plates 20 are not in contact with layer 24.

Two neighboring plates, that is, two plates which are not separated from each other by another plate 20, are thus separated by two portions of layer 22 and at least one portion of layer 24. In the example of FIG. 1, the space between two neighboring plates is filled with two portions of layer 22 and one portion of layer 24, the two portions of layer 22 being separated by the portion of layer 24. In other words, the upper surface of a plate 20 and the lower surface of a neighboring plate 20 are separated by a stack only including, in this order, a portion of layer 22, a portion of layer 24, and a portion of layer 22. The distance between two plates 20 is thus greater than or equal to the sum of twice the thickness of layer 22 and once the thickness of layer 24.

Capacitor 10 is for example covered with a protection layer 26. Layer 26 is for example made of an insulating material, for example, of silicon oxide.

As a variant, two neighboring plates may be separated by two portions of layer 22, by two portions of layer 24 and one portion of insulator, not shown, for example, air or a portion of layer 26, each portion of layer 22 being separated from the insulator portion by a portion of layer 24. Thus, the upper surface of a plate 20 and the lower surface of a neighboring plate 20 are separated by a stack only including, in this order, a portion of layer 22, a portion of layer 24, an insulator portion, not shown, a portion of layer 24, and a portion of layer 22.

FIGS. 2 to 9 illustrate steps, preferably successive, of a method of manufacturing the embodiment of FIG. 1. More precisely, FIGS. 2 to 9 illustrate the simultaneous forming of a plurality of capacitors such as that of FIG. 1.

FIG. 2 shows a cross-section view 2A and a perspective view 2B of a step of the method of manufacturing the embodiment of FIG. 1.

During this step, layer 14 and track 12 are formed. More generally, this step may include the forming of a stack 28 of insulating layers, layer 14 corresponding to the upper layer of stack 28.

Layer 12 for example includes lines of tracks 12. Said lines extend in the main direction of tracks 12, that is, the direction of the largest dimension of tracks 12. Layer 14 includes, in addition to tracks 12, conductive tracks 29.

Each track 12 of layer 14 is preferably adjacent to a track 29. In other words, layer 14 includes lines of tracks 9 extending parallel to the lines of tracks 12. Each line of tracks 29 is for example located between two lines of tracks 12.

Stack 28 for example includes a stack of layers 30, for example, made of the same material as layer 14, and of layers 32. Layers 32 for example have an identical thickness. Layers 30 for example have an identical thickness. Layers 32 for example have a thickness smaller than the thickness of layers 30. Layers 30 for example include conductive tracks 34, for example, made of the same material as tracks 12. Tracks 34 for example enable to form interconnects between tracks 12 and 29.

FIG. 3 shows a cross-section view 3A and a perspective view 3B of another step of the method of manufacturing the embodiment of FIG. 1.

During this step, layer 16 is formed on stack 28. Layer 28 preferably covers the entire structure resulting from the step of FIG. 2. Layer 28 particularly covers tracks 12, 29 and layer 14.

During this step, a stack 36 of layers is formed on layer 16. Stack 36 particularly covers tracks 12.

Stack 36 includes sacrificial layers 38 and conductive layers 40. The layers 38, 40 of stack 36 are alternately layers 38 and layers 40. Thus, each layer 38 is separated from the closest layer 38 by a layer 40.

The lower layer of stack 36, that is, the layer closest to tracks 12, rests on, and is preferably in contact with, layer 16. The lower layer of stack 36 is preferably a layer 38.

The upper layer of stack 36, that is, the layer most distant from tracks 12, is preferably a layer 38.

Layers 40 are made of the material of the plates 20 of FIG. 1, for example, of metal, for example, of titanium nitride. Layers 38 are made of a material capable of being selectively etched over the material of layers 40. Layers 38 are for example made of an insulating material, for example, of silicon oxide.

The layers 38 and 40 of stack 36 preferably have substantially constant thicknesses. Layers 40 preferably have a same thickness. The layers 38 of stack 36 located between two layers 40 preferably have a same thickness. The upper and lower layers 38 of stack 36, that is, the layer 38 most distant from layer 16 and the layer 38 closest to layer 16, for example have different thicknesses, preferably thicknesses greater than the thickness of the layers 38 located between layers 40.

The thickness of layers 38 is at least equal to the distance desired between two plates 20 of FIG. 1, that at least equal to the sum of twice the thickness of the layer 22 of FIG. 1 and of the thickness of layer 24. The thickness of the upper layer 38 of stack 36 is substantially equal to the height of the portion of pads 18 located above the plate 20 of FIG. 1 most distant from track 12.

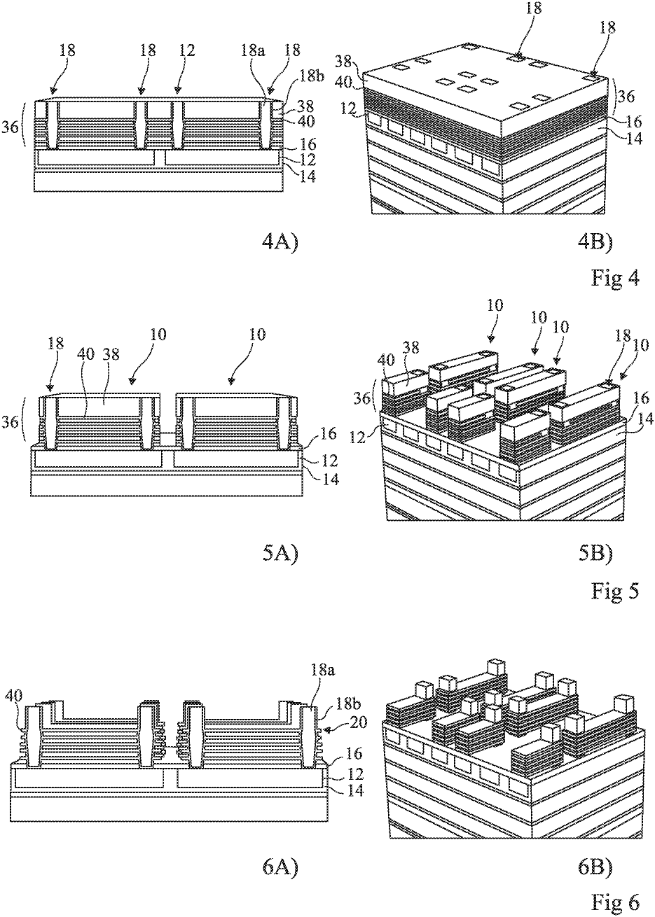

FIG. 4 shows a cross-section view and a perspective view of another step of the method of manufacturing the embodiment of FIG. 1.

During this step, pads 18 are formed. The forming of pads 18 includes the forming of cavities at the locations of pads 18, crossing stack 36 and layer 16. The cavities extend from the upper surface of stack 36, that is, the surface of stack 36 most distant from tracks 12, to the lower surface of layer 16, that is, the surface of layer 16 closest to tracks 12. The bottom of each cavity is thus formed by the upper surface of a track 12. Two cavities are formed in front of each track 12. Thus, two portions of each track 12 are exposed by cavities. The lateral walls of the cavities are formed by lateral walls of layers 38 and 40.

For example, the cavities are formed by the forming of an etch mask on stack 36 including openings in front of the locations of pads 18 and including the etching of layers 38, 40 and of layer 16.

This step then includes the forming of the sheath 18b of each pad 18. In other words, this step includes the forming of a layer made of the material of sheath 18b on the lateral walls and the bottom of each cavity. For example, a layer made of the material of sheath 18b is formed conformally over the entire structure resulting from the forming of the cavities, in particular on the lateral walls and the bottom of the cavities. The portions of said layer being located outside of the cavities are then removed.

This step further includes the forming of core 18a. In other words, the cavity is filled with the material of core 18a. For example, a layer made of the material of core 18a is formed on the structure resulting from the forming of sheaths 18b, the thickness of said layer being sufficient to totally fill the cavities. The portions of said layer being located outside of the cavities are then removed.

FIG. 5 shows a cross-section view and a perspective view of another step of the method of manufacturing the embodiment of FIG. 1.

During this step, stack 36 is etched to separate the stacks 36 of the different capacitors 10. Thus, the portions of stack 36 corresponding to each capacitor 10 are separated from one another. In particular, layers 40 are etched to form the plates 20 of FIG. 1.

For example, an etch mask, not shown, is formed on the structure resulting from the step of FIG. 4. The etch mask includes openings for example forming a gridding surrounding the locations of capacitors 10. Thus, the locations of capacitors 10 are covered with the etch mask. In particular, the mask includes openings extending parallel to the lines of tracks, said openings being each in front of a portion of layer 14 separating the lines of tracks. The portions of stack 36 in front of tracks 29 are located in front of openings in the mask and are thus etched. The mask further includes openings located in front of portions of layer 14 located between the tracks of a same line. An etch step, or a succession of etch steps, is then performed through the openings of the etch mask. The etch step is maintained until the upper surface of layer 16 is reached. Layer 16 is not removed during the etch step.

Each portion of stack 36 resulting from the etch step corresponds to a capacitor, and includes two pads 18. Each track 12 is covered with a single portion of stack 36. Each portion of stack 36 only covers a single track 12.

Preferably, the horizontal dimensions of each portion are smaller than the dimensions of the track 12 of the same capacitor 10. Thus, the portions of stack 36 are for example not located in front of the layer 14 laterally surrounding tracks 12.

FIG. 6 shows a cross-section view and a perspective view of another step of the method of manufacturing the embodiment of FIG. 1.

During this step, the layers 38 of stack 36 are removed. Layers 38 are removed from all the portions of stack 36. The removal of layers 38 is for example performed by an etching method, for example a plasma etching method, enabling to selectively etch the material of layers 38 over the material of layers 40. Preferably, layer 16 is not removed. The etching method preferably enables to selectively etch the material of layers 38 over the material of layer 16. Further, the material of core 18a is not removed during this etch step. The etching method enables for example to selectively etch the material of layers 38 over the material of cores 18a.

The material of layers 38 located above layer 16 is thus removed. Plates 20 are only in contact with air and with pads 18.

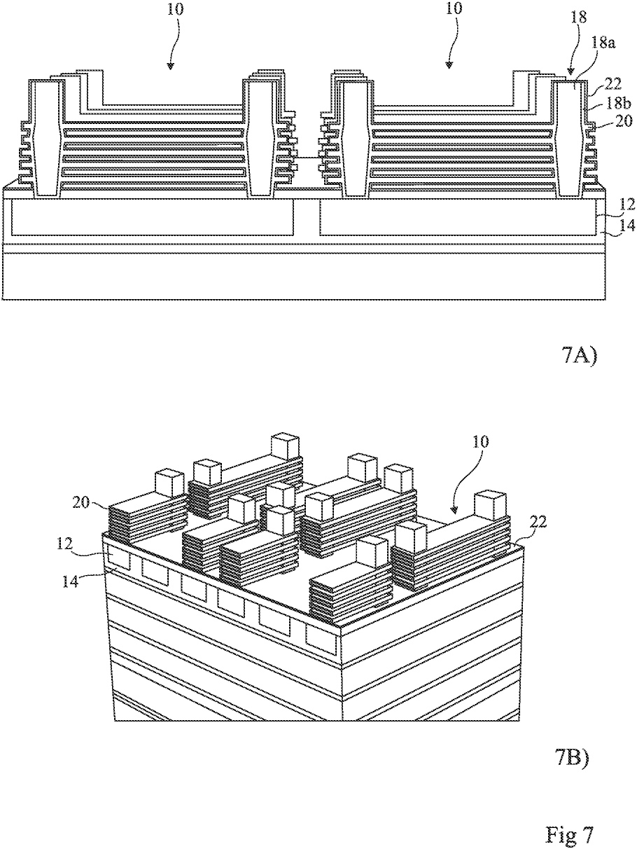

FIG. 7 shows a cross-section view and a perspective view of another step of the method of manufacturing the embodiment of FIG. 1.

During this step, layer 22 is formed. Layer 22 is formed conformally over the entire structure resulting from the step of FIG. 6.

Layer 22 is formed on all the exposed surfaces. In particular, layer 22 is formed on all the exposed surfaces of plates 20 and of pads 18. More particularly, layer 22 is formed on the upper and lower surfaces of plates 20, as well as on the lateral walls of plates 20. Layer 22 is further formed on the portions of pads 18 located between plates 20. Further, layer 22 is formed on the portions of the pads located under and above plates 20, in particular on the upper surface of pads 18. Layer 22 is preferably formed on the exposed portions of layer 16.

Each assembly including the pads 18 and the plates 20 of a capacitor 10, that is, the first electrode of said capacitor, is thus entirely covered with insulating layer 22.

The thickness of layer 22 is preferably substantially constant. The thickness of layer 22 is smaller than half the distance between two plates 20.

The portions of layer 22 located on a lower or upper surface of a plate 20 are separated from the portions of layer 22 located on a neighboring plate by an empty space.

Layer 22 is for example deposited by a method of deposition of thin atomic layers, for example, a method of ALD (“Atomic Layer Deposition”) type.

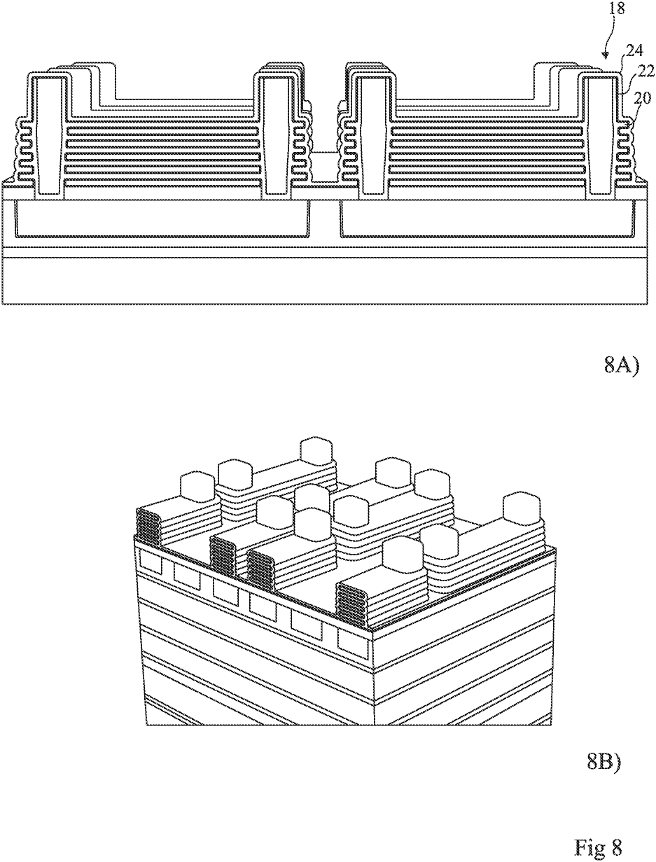

FIG. 8 shows a cross-section view and a perspective view of another step of the method of manufacturing the embodiment of FIG. 1.

During this step, layer 24 is formed. Layer 24 is formed conformally over the entire structure resulting from the step of FIG. 7.

Layer 24 is formed on all the exposed surfaces. In particular, layer 24 is formed on all the exposed surfaces of the portions of layer 22 covering plates 20 and pads 18. More particularly, layer 24 is formed on the portions of layer 22 covering the upper and lower surfaces of plates 20, as well as on the portions of layer 22 covering the lateral walls of plates 20. Layer 24 is further formed on the portions of layer 22 covering the portions of pads 18 located between plates 20. Further, layer 24 is formed on the portions of layer 22 covering the portions of the pads located under and above plates 20, in particular on the upper surface of pads 18. Layer 24 is preferably formed on the portions of layer 22 covering the exposed portions of layer 16.

Each portion of layer 22 covering the assembly including the pads 18 and the plates 20 of a capacitor 10 is thus entirely covered with insulating layer 24. Each portion of the assembly including the pads 18 and the plates 20 of a capacitor 10 is covered with a portion of layer 22 and with a portion of layer 24. Thus, each portion of the first electrode is separated from a portion of the second electrode by insulating layer 22.

In the example of FIG. 8, the space located between two neighboring plates 20 is filled with the two portions of layer 22 and the portion of layer 24 covering said portions of layer 22.

The thickness of layer 24 is preferably substantially constant. In the example of FIG. 8, the thickness of layer 24 is such that the sum of twice the thickness of layer 22 and once the thickness of layer 24 is substantially equal to the distance between two plates 20.

Layer 24 is for example deposited by a method of deposition of thin atomic layers, for example, a method of ALD (“Atomic Layer Deposition”) type.

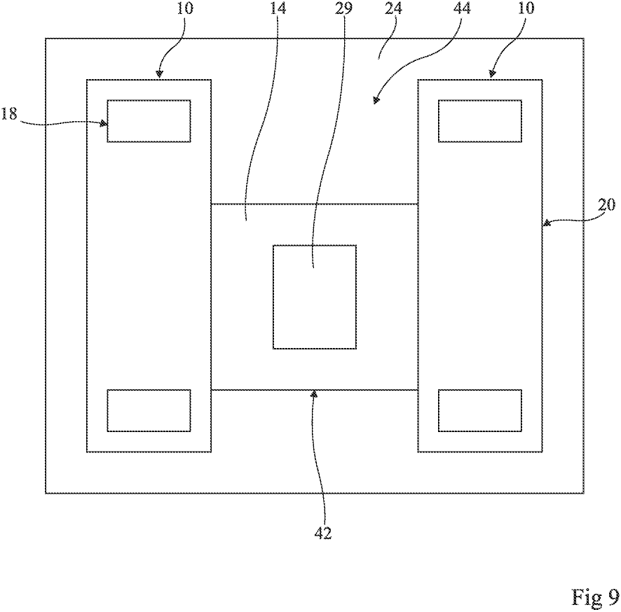

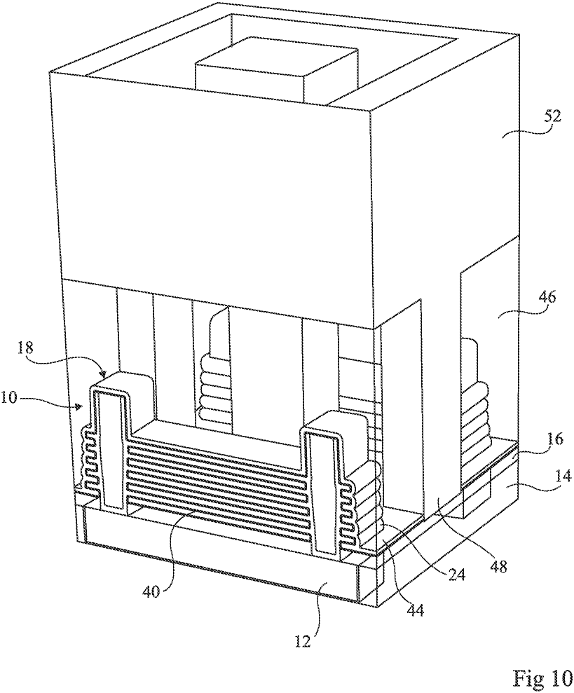

FIGS. 9 and 10 illustrate the forming of connections to the two electrodes of capacitors 10. In the example of FIGS. 9 and 10, the connections of capacitors 10 are common, to form a capacitor having a higher capacitance than a capacitor 10 alone. Other connection means may be used.

FIG. 9 shows a top view of another step of the method of manufacturing the embodiment of FIG. 1. More precisely, FIG. 9 shows a top view illustrating two neighboring capacitors 10 resulting from said step of the manufacturing method.

During this step, an opening 42 is formed through layers 16, 22, and 24 to expose track 29. More precisely, an opening 42 is formed in front of each track 29. In other words, the step of FIG. 9 includes the etching of a portion of layers 16, 22, and 24 covering track 29. For example, said portion of layers 16, 22, and 24 is located in front of track 29 and in front of a portion of layer 14 surrounding track 29. Thus, said portion of layer 14 surrounding track 29 is exposed by opening 42.

The step of FIG. 9 for example includes, before the etching of layers 14, 22, and 24, the forming of an etch mask, not shown, covering the structure resulting from the step of FIG. 8 and including an opening in front of opening 42. In particular, the etch mask covers, and protects, the assemblies including pads 18, plates 20, and the portions of layers 22 and 24 covering pads 18 and plates 20. Opening 42 does not extend over the assemblies including pads 18, plates 20, and the portions of layers 22 and 24 covering pads 18 and plates 20.

The dimensions of each opening 42 are preferably at least equal to the dimensions of track 29 located in front of said opening. In the plane of FIG. 9, the dimension of opening 42 in the direction perpendicular to the main direction of tracks 12, and thus of plates 20, is preferably smaller than the distance between the two closest stacks of plates 20, that is, the distance between two lines of capacitors. In the plane of FIG. 9, the dimension of opening 42 in the main direction of tracks 12, and thus of plates 20, is preferably smaller than the dimensions of plates 20 in the same direction.

At least a portion 44 of the stack including layers 16, 22, and 24 located between capacitors 10 is not etched, and was thus protected by the etch mask. Thus, the portions of layer 24 of the different capacitors 10 are electrically coupled to one another by portions 44. Thus, the second electrodes of the capacitors, that is, the portions of layer 24 of said capacitors, are coupled to one another.

FIG. 10 shows a perspective view of another step of the method of manufacturing the embodiment of FIG. 1.

During this step, an insulating layer 46 is formed on the structure resulting from the step of FIG. 9. Layer 46 is planarized so that the upper surface of layer 46 is planar, for example parallel to layer 16. Layer 46 is sufficiently thick to entirely cover capacitors 10 after planarization.

Vias 48 and 50 crossing layer 46 are formed. Each via 48 crosses layer 46 to reach a portion 44, more precisely the portion of layer 24 of a portion 44. Thus, each via 48 corresponds to the second electrode of capacitors 10. Each via 50 crosses layer 46 to reach a track 29. Thus, each via 50 corresponds to the first electrode of capacitors 10.

Conductive tracks 52 may be formed to couple vias 48 together or to couple vias 50 together.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

A device may be summarized as including at least one capacitor, the capacitor including an assembly of two metal pads and at least two metal tracks, each plate extending at least from one pad to the other, a first insulating layer conformally covering said assembly, a second conductive layer conformally covering the first layer.

A method of manufacturing a device including at least one capacitor may be summarized as including: a) the forming of an assembly of two metal pads and at least two metal plates, each plate extending at least from one pad to the other, b) the forming of a first insulating layer conformally covering said assembly; and c) the forming of a second conductive layer conformally covering the first layer.

Two neighboring plates of a same capacitor may be separated by two portions of the first insulating layer and one portion of the second conductive layer located between the two portions of the first insulating layer.

The pads may include a metal core and a sheath made of the same material as the plates.

The device may include a plurality of capacitors, the second layers of the capacitors being coupled by portions of the second layer.

The capacitor may include a conductive track in a third insulating layer of the device, the pads resting on the track.

The capacitor may include a fourth insulating layer covering the conductive track, the pads crossing the third insulating layer, the fourth layer being located between the plates and the track.

The portions of the assembly located above the fourth layer may be entirely covered with the first insulating layer, the first insulating layer being entirely covered with the second layer.

The method may include a step a0) preceding step a) during which the conductive track is formed in the third insulating layer, and the fourth layer is formed on the track and on the third layer.

Step a) may include a step a1) of forming of a stack of layers including an alternation of fifth layers made of the material of the plates and of sixth sacrificial layers.

The sixth layers may be made of a material selectively etchable over the material of the fifth layers.

Step a) may include, after step a1), a step a2) of etching of the stack to form the plates from the fifth layers.

Step a) may include, after step a2), a step a3) including the etching of the sixth layers.

Steps b) and c) may be performed by an atomic layer deposition method.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising at least one capacitor, the capacitor including:
two metal pads;
at least two metal plates, each plate extending at least from one pad to the other;
a first insulating layer conformally covering said assembly; and
a second conductive layer conformally covering the first layer.

2. The device according to claim 1, wherein two neighboring plates of a same capacitor are separated by two portions of the first insulating layer and one portion of the second conductive layer located between the two portions of the first insulating layer.

3. The device according to claim 1, wherein the pads include a metal core and a sheath made of the same material as the plates.

4. The device according to claim 1, comprising a plurality of capacitors, the second layers of the capacitors being coupled by portions of the second layer.

5. The device according to claim 1, wherein the capacitor includes a conductive track in a third insulating layer of the device, the pads resting on the track.

6. The device according to claim 5, wherein the capacitor includes a fourth insulating layer covering the conductive track, the pads crossing the third insulating layer, the fourth layer being located between the plates and the track.

7. The device according to claim 6, wherein the portions of the assembly located above the fourth layer are entirely covered with the first insulating layer, the first insulating layer being entirely covered with the second layer.

8. A method of manufacturing a device including at least one capacitor, the method, comprising:
forming of an assembly of two metal pads and at least two metal plates, each plate extending at least from one pad to the other,
forming a first insulating layer conformally covering said assembly; and
forming a second conductive layer conformally covering the first layer.

9. The method according to claim 8, wherein the capacitor includes a conductive track in a third insulating layer of the device, the pads resting on the track.

10. The method according to claim 9, wherein the capacitor includes a fourth insulating layer covering the conductive track, the pads crossing the third insulating layer, the fourth layer being located between the plates and the track.

11. The method according to claim 9, wherein the portions of the assembly located above the fourth layer are entirely covered with the first insulating layer, the first insulating layer being entirely covered with the second layer.

12. The method according to claim 11, comprising, prior to forming the assembly of two metal pads and at least two metal plates, forming the conductive track in the third insulating layer, and forming the fourth layer on the track and on the third layer.

13. The method according to claim 12, wherein forming the assembly of two metal pads and at least two metal plates includes forming of a stack of layers including an alternation of fifth layers made of the material of the plates and of sixth sacrificial layers.

14. The method according to claim 13, wherein the sixth layers are made of a material selectively etchable over the material of the fifth layers.

15. The method according to claim 14, wherein forming the assembly of two metal pads and at least two metal plates includes, after forming the stack of layers, etching the stack to form the plates from the fifth layers.

16. The method according to claim 15, comprising etching the sixth layers after etching the stack.

17. The method according to claim 13, including forming the first insulating layer and the second conductive layer by an atomic layer deposition method.

18. A device, comprising:
a substrate;
a conductive track in the substrate;
a pair of conductive pads each over the conductive track;
a plurality of conductive plates extending laterally between the pair of conductive pads and collectively corresponding to a first electrode of a capacitor;
a conductive material positioned over the conductive pads and between the plurality of conductive plates and corresponding to a second electrode of the capacitor; and
an insulating layer electrically isolating the conductive material from the conductive plates and electrically isolating the conductive material from the conductive pads.

19. The device of claim 18, wherein each conductive plate laterally surrounds each of the conductive pads.

20. The device of claim 18, wherein the insulating layer is in contact with a top surface of the conductive pads.
